(19) United States
(12) Patent Application Publication
(10) Pub. No.: US 2014/0095119 A1
(43) Pub. Date: Apr. 3, 2014

(54) SYSTEM AND METHOD FOR LOCATION-BASED CONSTRUCTION PROJECT MANAGEMENT

(71) Applicants: Ghang Lee, Seoul (KR); Jong Sung Won, Seoul (KR)

(72) Inventors: Ghang Lee, Seoul (KR); Jong Sung Won, Seoul (KR)

(73) Assignee: Industry-Academic Cooperation Foundation, Yonsei University, Seoul (KR)

(21) Appl. No.: 13/995,253

(22) PCT Filed: Jun. 13, 2012
(86) PCT No.: PCT/KR12/04641

§ 371 Date: Jun. 18, 2013

(30) Foreign Application Priority Data
Jun. 13, 2011 (KR) 10-2011-0056770

(51) Int. Cl. G06F 17/50

(52) U.S. Cl. CPC G06F 17/5004
USPC 703/1

(57) ABSTRACT

A system for location-based construction project management includes a design information storage section for storing a 2D plot or a 3D model of a building, a work place code storing means, being deployed at each work place of the building, and for storing location information of the work place, a wireless terminal being provided with local information of the work place and location information in addition to the work place code storing means, a work place mapping section for mapping the location information and a locational numeric data of the work place within the 2D plot or the 3D model stored in the design information storage section and a construction information storage section for storing the local information being provided into the wireless terminal, as linked with the locational numeric data mapped by the work place mapping section.

### BACKGROUND OF THE INVENTION

1. Field of the Invention

The present invention relates, in general, to a system and method for construction project management and, in particular, to a system and method for managing information about a construction project by automatically recognizing each working place of the construction project, sending work-related information collected at the construction project to the construction project management system, and storing the collected information by linking it to a corresponding location within a two-dimensional (2D) plot or a three-dimensional (3D) model.

2. Description of the Related Art

In general, an officer in charge of a construction project may visit places where work is carried on, to keep and manage information related to each place by taking notes and or pictures. In order to systematically arrange information collected during field patrol, the person in charge returns to a site office and reproduce or arrange or associate the collected information with problem areas of the project for uploading it to the management system. With massive data, this management method is problematic as very clumsy and inaccurate.

In order to overcome such a problem, a system which can search for location information of facilities using a mobile device, a global positioning system (GPS), a sensor or the like or search for real-time work reporting has been developed. However, GPS technology is difficult to be utilized indoors, to precisely locate a building due to a large error margin, and further to search for places at differing heights. Therefore, the GPS technology does not have good applicability to construction projects. Other than GPS, there are methods for detecting indoor location of a mobile device based on sensors or wireless network devices. However, these technologies still have problems of low accuracy.

The information disclosed in the Background of the Invention section is only for the enhancement of understanding of the background of the invention, and should not be taken as an acknowledgment or any form of suggestion that this information forms a prior art that would already be known to a person skilled in the art.

### SUMMARY OF THE INVENTION

Accordingly, the present invention has been made keeping in mind the above problems occurring in the related art, and a system and method for location-based construction project management according to the present invention has the following objects.

First, a wireless terminal carried by a person in charge of construction receives a unique identification code, an intensity of a signal or the like of an active sensor or a passive sensor, at each construction project, then firstly recognize the location, and then a correct direction is acquired using a direction sensor equipped within the wireless terminal. Information, such as pictures, memos or instructions, collected at the location is sent wirelessly in real time to a construction project management system. The system stores the collected information in a server without additional labor by linking the acquired location information and local information to a corresponding location within a 2D design plot or a 3D design model.

Second, it is intended to store work information of the construction site in real time by linking it to a design plan or a 3D model which represents the located place through a wireless terminal of the person in charge, without requiring additional job of taking down work information about the construction site by hand and putting it into the system.

Third, it is intended to transmit the local information and the location information in real time to the central server from the site, so that the local information collected from the construction project can be acknowledged in real time at the site office.

Fourth, the person in charge of construction, during field patrol, may be able to verify data stored in the construction project management system using the wireless terminal which he/she carries, further to check whether or not a problem that was found earlier has been solved, and to take follow-up measures if required.

The objects of the invention are not limited to those mentioned above, and the other objects which have not been mentioned above will be fully apparent to a person having ordinary skill in the art from the following description.

In order to achieve the above object, according to one aspect of the present invention, there is provided a system for location-based construction project management, comprising: a design information storage section being stored therein a 2D plot or a 3D model of a building; a work place code storing means, being deployed at respective work places of the building under construction, and being stored therein location information of the respective work places; a wireless terminal to be provided with local information of the work place and the location information from the work place code storing means; a work place mapping section wherein the location information which is inputted from the work place code storing means to the wireless terminal is mapped with respect to a locational numeric data of the work place within the 2D plot or the 3D model stored in the design information storage section; and a construction information storage section wherein the local information, acquired by the wireless terminal, is stored therein, as linked with the locational numeric data mapped with the location information by the work place mapping section.

The work place code storing means in accordance with the present invention may include at least one of a work place coordinates tag in the form of a printout whereon the coordinates of the work place is printed out or an electric device type sensor wherein the coordinates of the work place is stored.

The work place coordinates tag in accordance with the present invention may be configured as at least one of a QR code and a bar code, and the sensor comprises at least one of an NFC tag and an RFID tag.

The wireless terminal in accordance with the present invention may include a data input section, which includes at least one device from a keypad, a touchpad, a microphone and a camera, to receive local information using the device; and a work place code recognizing section, which includes at least one device from a camera, a scanner, an RFID receiver and an NFC receiver.

The wireless terminal in accordance with the present invention may be a mobile communication terminal which the person in charge of the construction project uses. The mobile communication terminal transmits the location information from the work place coordinate storing means to the work place mapping section, and transmits the inputted local information of the work place to the construction information storage section.

The design information storage section, the work place mapping section and the construction information storage section in accordance with the present invention may be placed in a server which manages the construction project.

The local information in accordance with the present invention may include at least one selected from among a photo of the work place, a video clip of the work place, material information of the work place, personnel information about the work place, a construction schedule for the work place, a construction budget for the work place, information about whether or not the work place has been inspected and a note pertaining to the work place.

The wireless terminal in accordance with the present invention may receive a graphically representative information about the 2D plot or the 3D model stored within the design information storage section and may display the received graphically representative information thereon, or may receive the local information stored in the construction information storage section and display the received local information thereon.

The system may further include a display unit for extracting a part of local information of the work place selected by a user from among the local information stored in the construction information storage section, and for displaying the extracted local information thereon.

According to another aspect of the present invention, also provided is a method for location-based construction project management, including step S1 of storing a 2D plot or a 3D model of a building in the design information storage section;

step S2 of deploying work place code storing means for representing locations in the 2D plot or the 3D model at respective work places of the building under construction;

step S3 of providing the wireless terminal of a person in charge of the work place with the location information of the work place code storing means deployed at the step S2 and local information of the work place;

step S4 of mapping a locational numeric data of the work place within the 2D plot or the 3D model, based on the location information of the work place code storing means provided at the step S3; and

step S5 of storing the local information of the work place, provided with at the step S3, in the construction information storage section, with respect to each of the work places, as linked to the locational numeric data of the work place mapped at the step S4.

The method for location-based construction project management in accordance with the present invention may further include displaying an information with respect to the work place chosen by a user from a graphical information of the 2D plot or the 3D model stored in the design information storage section or the local information stored in the construction information storage section onto a wireless terminal or an additional display.

The system and method for location-based construction project management according to the invention have the following advantages.

First, even if a person in charge of a construction project is not necessarily skilled in the construction industry, he/she can receive a unique identification code of an active sensor or a passive sensor, the intensity of a signal, or the like, at each construction project using a mobile device, such as a mobile phone or a tablet PC, which can transmit and receive data, so that the location of facility where the person in charge is located is automatically recognized. Based on the location information of facilities recognized in this fashion, it is possible to automatically store collected construction information, such as a photo or instructions, memo etc. by linking it to a corresponding space in the a 2D design plot or a 3D design model.

Second, it is possible to automatically link and store the collected local information in the project management system in real time using wireless communication technologies, thereby reducing additional labor and time which would otherwise be spent for additional documentation for site monitoring and management. This can consequently simplify and automate a report system.

Third, it is possible to check or display in real time the status of the construction project or errors in the construction, and create a variety of alternatives for processes and costs, thereby efficiently supporting construction management.

Fourth, since the invention can be implemented regardless of languages, it can be applied in foreign markets. The effects of the invention are not limited to those mentioned above, and the other advantages which have not been mentioned above will be fully apparent to a person having ordinary skill in the art from the following description.

### BRIEF DESCRIPTION OF THE DRAWINGS

The above and other objects, features and advantages of the present invention will be more clearly understood from the following detailed description when taken in conjunction with the accompanying drawings, in which:

FIG. 1 is a configuration view schematically showing a system for location-based construction project management according to an embodiment of the invention;

FIG. 2 is a structural view showing individual components of the system for location-based construction project management according to an embodiment of the invention;

FIG. 3 shows an example of the process of locating a correct location in a 3D model by photographing a work place coordinates tag using a wireless terminal according to the invention;

FIG. 4 shows the process of photographing a photo at a work place which has been located;

FIG. 5 shows the process of storing the information photographed at the construction project by matching it to a location of a 3D design plot; and

FIG. 6 is a flowchart schematically showing a method for location-based construction project management according to an embodiment of the invention.

### DETAILED DESCRIPTION OF THE INVENTION

Reference will now be made in detail to various embodiments of the present invention, examples of which are illustrated in the accompanying drawings and described below. While the invention will be described in conjunction with exemplary embodiments thereof, it is to be understood that the present description is not intended to limit the invention to those exemplary embodiments. On the contrary, the invention is intended to cover not only the exemplary embodiments, but also various alternatives, modifications, equivalents and other embodiments that may be included within the spirit and scope of the invention as defined by the appended claims.

While terms such as “first,” “second,” “A” and “B” can be used in describing various elements, it should be understood that these terms do not limit those elements but merely discriminate those elements from others. For instance, first element can be named the second element, and vice versa, without departing the scope of protection of the present invention. The term “and/or” shall include the combination of a plurality of listed items or any of the plurality of listed items.

Unless clearly used otherwise, some expressions in the singular number may include a plural meaning. In the present description, an expression such as “comprising” or “consisting of” is intended to designate a characteristic, a number, a step, an operation, an element, a part or combinations thereof, and shall not be construed to preclude any presence or possibility of one or more other characteristics, numbers, steps, operations, elements, parts or combinations thereof. Hereinafter a system for location-based construction project management and a method thereof will be described in detail with reference to the drawings.

The term “work place” used herein refers to a specific place, of a building or a facility, where any kind of construction work is currently carried out. For instance, the work place can be a detailed place such as the left wall of a rest room of a 10^{th} door on a 5^{th} floor of a building.

Although the work place may be a zone having a specific area, it may be partitioned depending on the functions of the zone if sections of the zone which is constructed in the building have different functions. In addition, the work place may be defined depending on likelihood or relation of materials which are used in construction. For example, work places can be variously partitioned as a front door on the floor, a lobby of the floor, section A of the internal wall of the floor of an apartment.

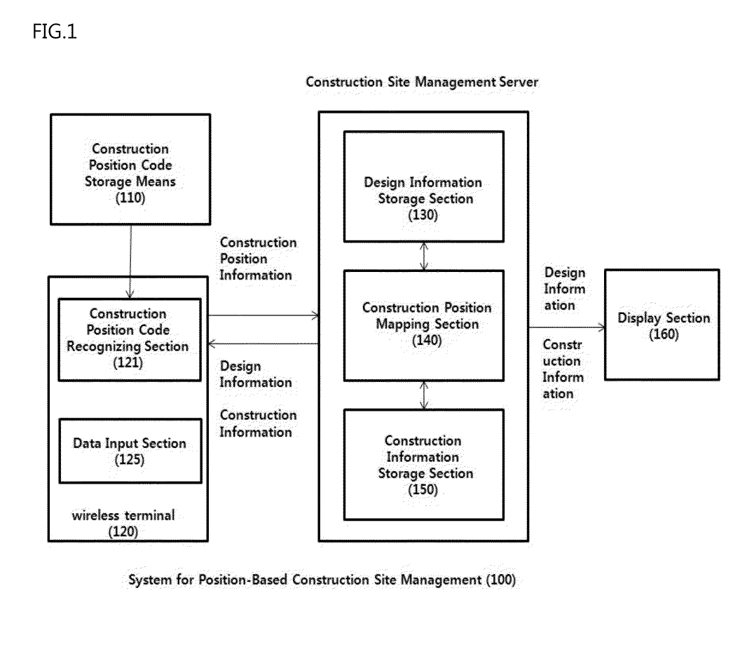

Before the detailed description with reference to the drawings, it should be understood that constituent elements of the invention are merely distinguished according to their main functions. Specifically, two or more constituent elements which will be described later may be combined into one constituent element, or one constituent element may be divided into two or more constituent elements having more specified functions. Each constituent element which will be described later may additionally carry out some or all of the function of another constituent element in addition to its main function, or some of the main function of one constituent element may be carried out exclusively by another constituent element. Therefore, the presence of the constituent elements which will be described herein should be interpreted based on their functions. The configuration of the constituent elements of a system for location-based construction project management 100 according to the invention may be different from FIG. 1 as long as they can realize the object of the invention.

FIG. 1 is a configuration view schematically showing a system for location-based construction project management 100 according to an embodiment of the invention.

A location-based service associated with a mobile communication terminal generally refers to a service which uses a position tracking function using a global positioning system (GPS) device of the mobile communication terminal. However, according to the invention, the term “location based” does not refer to the GPS of the mobile communication terminal, but to the location information (the coordinates) stored in coordinates tags or sensors which are disposed specific sections of a construction project where construction work is being carried out.

The system for location-based construction project management 100 according to the invention includes: a design information storage section 130 for storing a 2D plot or a 3D model of a building; a work place code storing means 110, being deployed at respective work places of the building under construction, for storing location information of the respective work places; a wireless terminal 120 for being provided with local information of the work place and the location information from the work place code storing means 110; a work place mapping section 140 for mapping the location information which is provided from the work place code storing means 110 to the wireless terminal 120 and a locational numeric data of the work place within the 2D plot or the 3D model stored in the design information storage section 130; and a construction information storage section 150 for storing the local information being provided with the wireless terminal 120, as linked with the locational numeric data mapped by the work place mapping section 140.

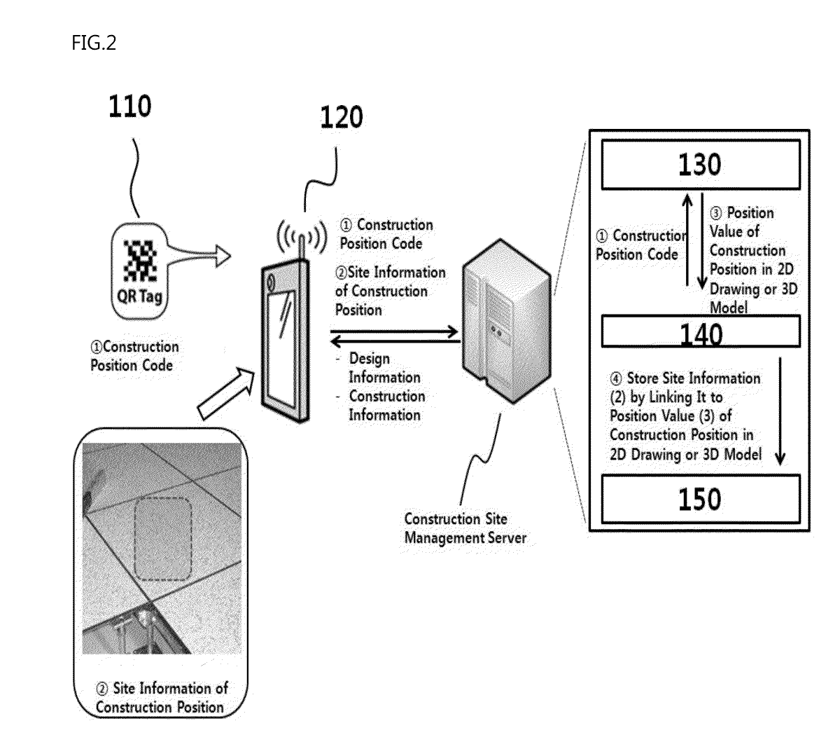

As shown in FIG. 1 and FIG. 2, it is preferable that the design information storage section 130, the work place mapping section 140 and the construction information storage section 150 be basically included in one integrated server. In FIG. 1, the block which encloses the design information storage section 130, the work place mapping section 140 and the construction information storage section 150 is named a construction project management server.

The 3D model employed in the invention is included in data, such as BIM (building information model) information, in which construction related information is matched and stored depending on each work place or structural element. Of course, in some cases, the storage space, or the server, may be detached and the design information and the matching construction information may be stored in physically separate servers.

The design information storage section 130 basically stores therein the 2D plot or the 3D model. It is possible to acquire the correct location of each section which is under construction by mapping the designed plan and the local information. Furthermore, any information about each section and its construction cost together with information about the material of construction members used in each section and the construction cost can be stored in the design information storage section 130.

The work place code storing means 110 are deployed at respective work places. A unique code, or location information, for identifying a work place is stored in the work place code storing means 110. The work place code storing means 110 may be at least one of a work place coordinates tag in the form of a printout whereon the coordinates of the work place is printed or an electric device type sensor wherein the coordinates of the work place is stored.

The work place coordinates tag may use a QR code, a bar code or the like. The sensor may be implemented as one or more of a near field communication (NFC) tag or a radio frequency identification device (RFID) tag. The RFID tag is divided into an active RFID tag and a passive RFID tag. The active RFID tag which transmits information by automatically recognizing an RFID receiver is more preferable.

The work place coordinates tag or the sensor stores therein the unique code of the work place, whereby the location in the 2D plot or the 3D model stored in the design information storage section 130 can be detected.

In the meantime, the work place coordinates tag or the sensor according to the invention may be substituted with a variety of marks or devices that a person having ordinary skill in the art can use. It is preferred that at least one work place coordinates tag or sensor be disposed at every work place.

A variety of methods can be used in order to detect the work place. For instance, it shall be assumed that a work place coordinates tag or a sensor attached to a rest room of a 10^{th} door on a 5^{th} floor of a building contains therein a work place code from which information including the direction can be acquired.

First, it is possible to deploy coordinates tags or sensors on all of four walls and transmit the work place code of each wall via the wireless terminal, so that local information can be stored in the system for location-based construction project management 100. However, this method increases a cost because a large number of coordinates tags are required.

Second, it is possible to dispose the work place coordinates tag or sensor, where the work place code including the direction information is stored, on only one wall, and check the direction information of the wall using a direction sensor of the wireless terminal. Therefore, the second method is more preferable.

Assuming that the work place coordinates tag is disposed on the left wall of the rest room of the 10^{th} door on the 5^{th} floor of the building, the work place coordinates tag contains therein information indicating that the location where the coordinates tag is disposed at present is the left wall of the bathroom. When a person in charge of the construction project turns the wireless terminal to the left or right with respect to the direction in which the coordinates tag is disposed, the direction sensor inside the wireless terminal can recognize the direction in which the front section of the wireless terminal is oriented at present.

The direction (relative direction) in which the front section of the wireless terminal 120 faces at present is acquired based on the work place and the direction (reference direction) stored in the work place coordinates tag on the left wall. The relative direction together with the construction code stored in the work place coordinates tag is sent to the work place mapping section 140. Consequently, the information including even the specific direction at the construction project is sent to the work place mapping section.

The wireless terminal 120 includes a data input section 125 and a work place code recognizing section 121. The data input section 125 includes at least one device selected from among a keypad, a touchpad, a microphone and a camera, and receives local information using that device(s). The work place code recognizing section 121 includes at least one device selected from among a camera, a scanner, an RFID receiver and an NFC receiver.

It is preferred that the data input section 125 with which the person in charge of the construction project inputs the local information be included in the wireless terminal 120. However, this is not intended to be limiting. It is of course possible to use input means that are physically separate from the wireless terminal 120.

The work place code recognizing section 121 is a component into which the code stored in the work place code storing means 110 is inputted, and the data input section 125 is a component into which the local information of the work place is inputted.

The QR code or bar code can be a printout that is attached at a specific location of the work place. The coordinate information of the present work place stored in the QR code or bar code is inputted into the wireless terminal 120 via the camera or scanner of the work place code recognizing section 121.

In the case of the active RFID, as the RFID receiver included in the work place code recognizing section 121 approaches the active RFID tag, the work place is automatically transmitted to the RFID receiver.

The wireless terminal 120 according to the invention can be one of various types of wireless terminals. The wireless terminal 120 transmits the information of the work place coordinates tag or the sensor to the work place mapping section 140 using the work place code recognizing section 121, and transmits the local information of the work place to the construction information storage section 150 using the work place code recognizing section 121.

The wireless terminal 120 according to the invention can be implemented as a mobile communication terminal that is distributed to each individual. For instance, it is possible to photograph the QR code or the like using the camera of the mobile communication terminal or receive the work place code using the RFID receiver which can perform data communication with the mobile communication terminal, and receive image information, a video clip, text information or voice information about the site using the camera, keypad, touchpad or microphone of the mobile communication terminal.

Specific local information may be at least one selected from among a picture of the work place, information about site materials used at the work place, information about a person in charge of the work place, a site construction schedule for the work place, a cost of construction of the work place, information about whether or not the work place has been inspected and a notice explaining the status of the construction at the work place.

The design information storage section 130, the construction information storage section 150 and the work place mapping section 140 have been described as separate components, since they have different functions. However, as shown in FIG. 1 and FIG. 2, they are basically placed in the same construction project management server. Of course, they may be placed in different servers, or the work place mapping section 140 may be implemented as an application that runs in the wireless terminal 120. When the work place mapping section 140 is separately configured, the computer having the work place mapping section 140 disposed therein acts as a clouding computer.

The work place mapping section 140 receives the work place code, or the work place information, stored in the work place code storing means 110, via the wireless terminal 120, and maps a locational numeric data (coordinates information or the like) of an accurate location in the 2D plot or the 3D model stored in the design information storage section 130 with the work place code.

The route along which the local information is finally inputted into the construction information storage section 150 can have a variety of shapes. First, the work place mapping section 140 can store the local information received from the wireless terminal 120 at the locational numeric data of the work place by linking it to the corresponding location within the 2D plot or the 3D model. Second, the wireless terminal 120 can send the local information to the construction information storage section 150, and store it linked to the locational numeric data of the work place of the work place mapping section 140.

The person in charge of the construction project is required to check construction-related notices which were recorded in advance while examining the work place stored in the construction information storage section 150. This is because it is necessary to check whether or not any problems that occurred at the site after the local information was inputted have been solved. In addition, the person in charge of the work place may be required to inspect the drawing of the work place.

For this, the wireless terminal can receive information about the 2D plot or the 3D model stored in the design information storage section 130 and display it thereon, or receive the local information stored in the construction information storage section 150 and display it thereon. Referring to FIG. 1 and FIG. 2, this corresponds to data that are sent from the construction project management server to the wireless terminal 120.

In addition, the local information or drawing information may be displayed on a separate display device rather than the wireless terminal 120. In FIG. 1, a display section 160 is depicted as a separate component. This means that a display system is configured in such a fashion that a separate computer device which a manager uses rather than a display device of the person in charge of the site displays the design information or the local information stored in the construction project management server.

Of course, the display section 160 can be implemented as a component that is included in the display device of the wireless terminal 120.

In the meantime, the 3D model stored in the design information storage section 130 includes not only the design drawing, but also information about materials and information about costs. Therefore, the person in charge of the construction project can find various parts of information that he/she wants in the design information storage section 130 and output it.

Further, when the person in charge of the construction project intends to check whether or not he/she previously inspected the work place where he/she is at present, information about whether or not the work place has been inspected is searched for within the local information stored in the construction information storage section 150, and is then displayed on the wireless terminal 120 of the user or the separate display section 160.

When the display section 160 is included in the wireless terminal 120 rather than being configured as a separate device, it is possible to select a part of local information that he/she wants using the input device, such as the keypad, in the wireless terminal 120. That is, when the person in charge of the construction project selects the local information using the input device in the wireless terminal 120, only the part of local information that he/she wants from within the local information stored in the construction information storage section 150 is displayed on the display section 160 in the wireless terminal 120.

FIG. 2 is a structure view showing individual components of the system for location-based construction project management 100 according to an embodiment of the invention. The separate display section 160 is not shown in FIG. 2.

The work place coordinates tag is shown in FIG. 2 as being a QR tag by way of example. The QR tag is photographed using the wireless terminal 120 of the person in charge of the construction project and is sent to the work place mapping section 140, which in turn maps the locational numeric data of the work place in the 2D plot or the 3D model using the work place code stored in the QR tag. The local information is stored with respect to the mapped locational numeric data of the work place in the construction information storage section 150.

The person in charge of the construction project collects the local information of the work place using the data input section 125 of the wireless terminal 120. In FIG. 2, the specific photograph of the work place is depicted as being taken using a camera by way of example. The local information collected in this fashion is stored in the construction information storage section 150, and linked to the locational numeric data of the work place detected by the work place mapping section 140. Consequently, the collected local information is automatically linked in real time to the corresponding location within the 2D plot or the 3D model. Therefore, it is possible to manage the construction project using the collected local information.

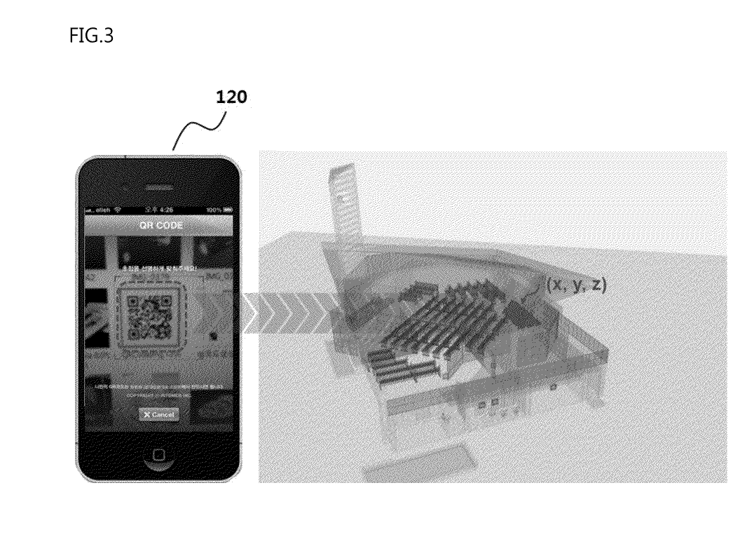

FIG. 3 shows an example of the process of locating a correct location in a 3D model by photographing a work place coordinates tag using a work place code recognizing section of the wireless terminal 120 according to the invention. The left part of FIG. 3 shows a mobile communication terminal, whereas the right part of FIG. 3 shows a 3D model.

The work place mapping section 140 can automatically find a correct corresponding location within the 3D model using a work place code received from the tag, such as a QR code, or the sensor. In FIG. 3, an example of photographing the QR code is shown. The location marked with (x,y,z) in the 3D model of right side corresponds to the work place where the QR code is placed at present. While the location is marked with (x,y,z), it will appear in practice as coordinates represented with specific numeric expressions.

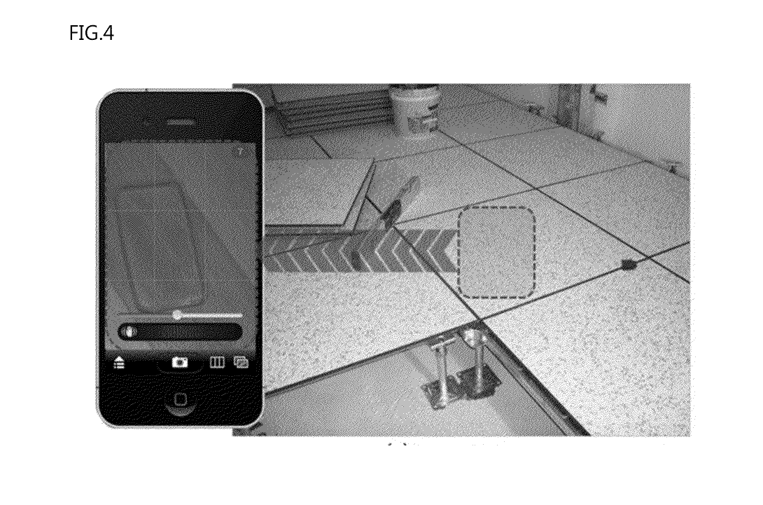

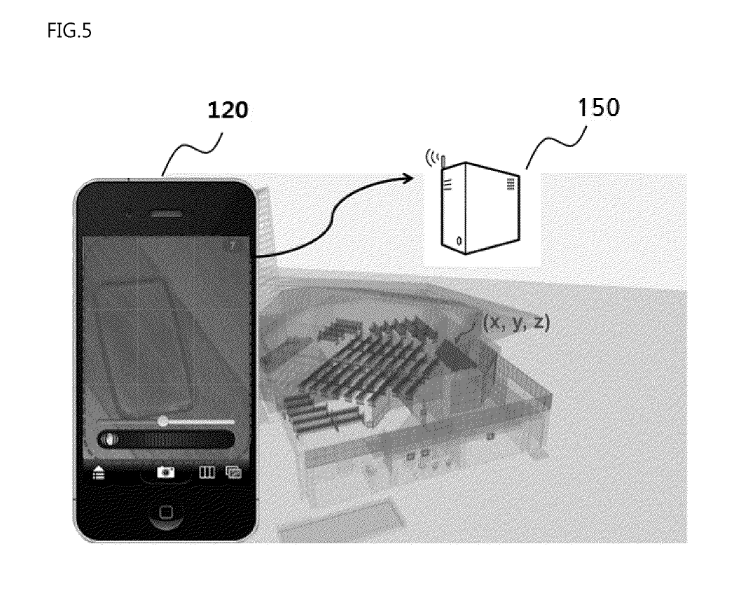

FIG. 4 shows the process of photographing a picture at a work place which has been located, and FIG. 5 shows the operation of storing the information, which was photographed at the construction project, together with its location information by linking them to a location of a 3D design drawing.

Referring to the process in FIG. 4, after the location information of the present work place is acquired using the QR code in FIG. 3, the person in charge of the construction project is taking a picture of the status of the construction of the present work place using the mobile communication terminal. FIG. 5 shows the process in which the local information photographed in FIG. 4 is stored together with the location information of the present work place in the construction information storage section 150.

A description will be given of the method for location-based construction project management according to the invention. In the following description, some features will be described in brief, since they are identical to those of the above-described system for location-based construction project management 100.

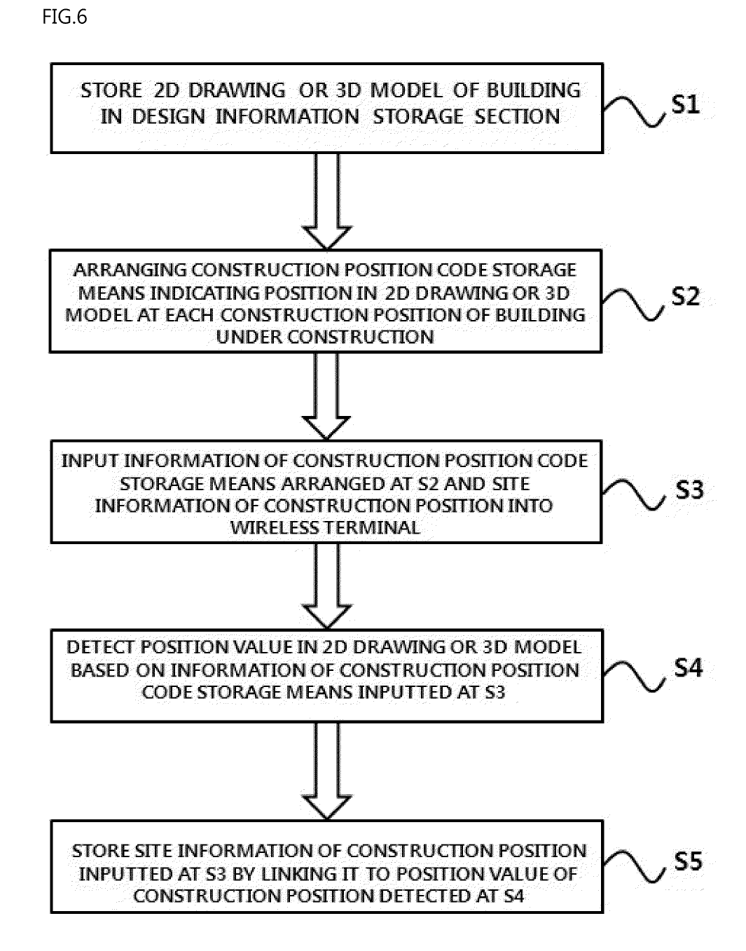

FIG. 6 is a flowchart schematically showing the method for location-based construction project management according to an embodiment of the invention.

The method for location-based construction project management according to an embodiment of the invention includes a step S1 of storing a 2D plot or a 3D model of a building in the design information storage section 130, a step S2 of deploying work place code storing means 110 for indicating a location in the 2D plot or the 3D model at each work place of the building under construction, a step S3 of providing the wireless terminal 120 of a person in charge of the work place with the location information of the work place code storing means 110 deployed at the step S2 and the local information of the work place, a step S4 of mapping a locational numeric data of the work place in the 2D plot or the 3D model, based on the location information of the work place code storing means 110 provided at the step S3, and a step S5 of storing the local information of the work place provided at the step S3 in the construction information storage section 150 with respect to the work place, as linked to a locational numeric data of the work place mapped at the step S4.

The work place code storing means 110 at the step S2 correspond to a work place coordinates tag in the form of a printout whereon the coordinates of the work place is printed or an electric device type sensor wherein the coordinates of the work place is stored.

The work place coordinates tag includes at least one selected from among a QR code, a bar code, an NFC tag and an RFID tag.

In the case of the QR code or the bar code, the coordinates information is inputted into the wireless terminal 120 via the camera or scanner in the wireless terminal 120. In the case of the active RFID tag, the coordinates information is inputted into the wireless terminal 120 via the RFID receiver in the wireless terminal 120.

While location detection at the step S4 may be carried out by the wireless terminal 120 in the step S3, the locational numeric data of the work place is automatically mapped in the 2D plot or the 3D model based on the work place code received from the construction project management server.

The local information at the step S3 may be at least one selected from among a photo of the work place, a video clip of the work place, information about materials used at the work place, information about a person in charge of the work place, a site construction schedule for the work place, a construction budget for the work place, information about whether or not the work place has been inspected and a note pertaining to the work place.

The method for location-based construction project management according to an embodiment of the invention may also include a step S6 of displaying any information of the work place, which is selected by a user from among the graphically representative information about the 2D plot or the 3D model stored in the design information storage section 130 and the local information stored in the construction information storage section 150, on the wireless terminal 120 or the separate display section 160.

In an example, information that can be displayed on the display section can be design information, information about a cost stored in the 3D model, information about a person in charge of the work place stored in the construction information storage section 150, a note pertaining to the work place, or the like.

Although the exemplary embodiments of the present invention and the drawings attached to the specification have been described for illustrative purposes, various modifications and changes are possible to a person having ordinary skill in the art without departing from the scope and spirit of the invention as disclosed in the accompanying claims.

1. A system for location-based construction project management, comprising:
a design information storage section for storing a 2D plot or a 3D model of a building;
a work place code storing means, deployed at respective work places of the building under construction, for storing location information of the respective work places;
a wireless terminal for acquiring local information of the work place to transmit the local information of the work place to a construction information storage section, for receiving the local information stored within the construction information storage section to display thereon, for acquiring the location information from the work place code storing means to transmit the location information to a work place mapping section, and for receiving the 2D plot or the 3D model stored within the construction information storage section to display thereon;
the work place mapping section for mapping the location information acquired from the work place code storing means by the wireless terminal is with to a locational numeric data of the work place within the 2D plot or the 3D model stored in the design information storage section; and
the construction information storage section for receiving the locational numeric data of the work place mapped with the location information of the work place code storing means from the work place mapping section, and for storing the local information, transmitted from the wireless terminal, as linked with the locational numeric data,
wherein the work place code storing means comprise at least one of: a work place coordinates tag containing the coordinates of the work place in a form of a printout and an electric device type sensor storing the coordinates of the work place.

2. (canceled)

3. The system according to claim 1, wherein the work place coordinates tag comprises at least one of a QR code and a bar code, and the sensor comprises at least one of an NFC tag and an RFID tag.

4. The system according to claim 1, wherein the wireless terminal comprises:
a data input section, including at least one device selected from among a keypad, a touchpad, a microphone and a camera, for receiving local information using the device; and
a work place code recognizing section including at least one device from among a camera, a scanner, an RFID receiver and an NFC receiver.

5. (canceled)

6. The system according to claim 1, wherein the design information storage section, the work place mapping section and the construction information storage section are placed in a server which manages the construction project.

7. The system according to claim 1, wherein the local information comprises at least one selected from among a photo of the work place, a video clip of the work place, information about materials used at the work place, information about the person in charge of the work place, a site construction schedule for the work place, a construction budget for the work place, information about whether or not the work place has been inspected and a note pertaining to the work place.

8. The system according to claim 1, wherein the wireless terminal receives a graphically representative information with respect to the 2D plot or the 3D model stored within the design information storage section and displays the received graphically representative information thereon, or receives the local information stored in the construction information storage section and displays the received local information thereon.

9. The system according to claim 1, further comprising a display unit for extracting a part of local information of the work place selected by a user from among the local information stored in the construction information storage section, and for displaying the extracted local information thereon.

10. A method for location-based construction project management, comprising:
storing a 2D plot or a 3D model of a building within a design information storage section;
acquiring, by a wireless terminal of a person in charge of a work place, location information of a work place code storing means deployed at respective work places of the building under construction
so as to represent respective locations within the 2D plot or the work place 3D model, transmitting the location information to a work place mapping section, and transmitting local information of the work place to a construction information storage section;
mapping, by the work place mapping section, the location information acquired from the work place code storing means by the wireless terminal with a locational numeric data of the work place within the 2D plot or the 3D model, based on stored in the design information storage section; and
receiving, the construction information storage section, the locational numeric data of the work place mapped with the location information of the work place code storing means from the work place mapping section, and for storing the local information, transmitted from the wireless terminal, as linked with the locational numeric data,
wherein the wireless terminal receives the local information stored in the construction information storage section to display thereon, and receives the 2D plot or the 3D model stored in the design information storage section to display thereon, and
wherein the work place code storing means comprise at least one of: a work place coordinates tag containing the coordinates of the work place in a form of a printout and an electric device type sensor storing the coordinates of the work place.

11. (canceled)

12. The method according to claim 8, wherein the work place coordinates tag comprises at least one of a QR code and a bar code, and the sensor comprises at least one of an NFC tag and an RFID tag.

13. The method according to claim 8, wherein the local information comprises at least one selected from among a photo of the work place, a video clip of the work place, information about materials used at the work place, information about the person in charge of the work place, a site construction schedule for the work place, a construction budget for the work place, information about whether or not the work place has been inspected and a note pertaining to the work place.

14. The method according to claim 8, further comprising displaying a graphically representative information with respect to the work place chosen by a user from a graphical information of the 2D plot or the 3D model stored in the design information storage section, or the local information stored in the construction information storage section on the wireless terminal or an additional display.
